(19) United States
(12) Patent Application Publication
(10) Pub. No.: US 2007/0099370 A1
(43) Pub. Date: May 3, 2007

(54) Method for manufacturing semiconductor device

(76) Inventors: Kazuaki Nakajima, Kamakura-shi (JP); Tomohiro Saito, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/524,237

(22) Filed: Sep. 21, 2006

(30) Foreign Application Priority Data
Sep. 22, 2005 (JP) 2005-275996

(51) Int. Cl. H01L 21/8238

(52) U.S. Cl. 438/199

(57) ABSTRACT

A method for manufacturing a semiconductor device includes forming a gate insulating film on a semiconductor substrate, and forming a gate electrode comprising a metal semiconductor compound layer and having a predetermined gate length on the gate insulating film, the forming the gate electrode including forming a polycrystalline semiconductor film having an average grain diameter below a specific size depending on the predetermined gate length and including at least one of silicon and germanium, the average grain diameter of the semiconductor film being 5 nm or more and 90 nm or less, forming a metal film on the semiconductor film, and converting whole of the semiconductor film into the metal semiconductor compound layer by reacting the semiconductor film and the metal film by heat treatment.

### CROSS-REFERENCE TO RELATED APPLICATIONS

This application is based upon and claims the benefit of priority from prior Japanese Patent Application No. 2005-275996, filed Sep. 22, 2005, the entire contents of which are incorporated herein by reference.

### BACKGROUND OF THE INVENTION

1. Field of the Invention

The present invention relates to a method for manufacturing a semiconductor device comprising a gate electrode formed of a metal semiconductor compound layer.

2. Description of the Related Art

Heretofore, in order to realize a high performance MOSFET, miniaturization of the device has been pursued. However, as the generation advances, high performance is becoming difficult to achieve. It is said that there is a limit to the scaling (thinning) of a gate oxide film for the device subsequent to 0.1 μm generation.

The reason is because, as the gate oxide film becomes thinner, increase in gate leak current due to tunnel current becomes obvious. Another reason is that, in this generation, depletion of a polysilicon gate electrode cannot be ignored. The depletion of the polysilicon gate electrode causes increase in thickness of effective oxide film of the gate oxide film. This hinders the scaling of the gate oxide film.

Hence, a technology using a gate insulating film (high-k film) higher in dielectric constant than the silicon oxide film in place of the gate oxide film and a technology using a metal gate electrode in place of the polysilicon gate electrode have been proposed.

In the former technology using the high-k film, a physical film thickness of the gate insulating film can be made thicker than a case of using the gate oxide film. Thereby, increase in tunnel current can be suppressed. On the other hand, in the latter technology of using the metal gate electrode, occurrence of depletion of the gate electrode can be suppressed. Thereby, increase in effective oxide film thickness of the gate insulating film can be suppressed.

In recent years, particularly, material development of the high-k film has been actively performed, and new materials such as ZrO₂, HfO₂, and the like have been picked up by academic institution. Thinning of equivalent oxide thickness has been brought into competition. However, it will take time to start discussion on the new materials about subject matter including reliability as in the conventional silicon oxide film

On the other hand, compared with the high-k film, study for the metal gate electrode seems to be less active. However, as shown in the road map of ITRS 2003 version, in the area below 1.0 nm in physical thickness of gate insulating film, it has become difficult to realize a transistor by conventional polycrystalline silicon gate electrode.

In a case where equivalent oxide thickness is less than 1 nm, depletion of the gate electrode rises approximately 3 nm increase in film thickness. In order to extend the life of the silicon system oxide film till this generation, development of the metal gate electrode is essential. As one type of the metal gate electrode, there exists a full-silicide electrode (J. kedziereski et al., “metal-gate FinFET and fully-depleted SOI devices using total gate silicidation”, IEDM 2002, p.247-250 (2002), J. Kedzierski et al., “Threshold voltage control in NiSi-gated MOSFETs through silicidation induced impurity segregation (SIIS)”, IEDM2003, P.315-318 (2003), J. Kedzierski et al., “Issues in NiSi-gated FDSOI device integration”, IEDM2003, p.441-444 (2003)). Since the full-silicide electrode process is excellent in adjustability with the conventional CMOS process, development competition has been promoted.

However, according to the conventional full-silicide electrode process, particularly in case of a fine pattern, fluctuation in sheet resistance of the gate electrode becomes large.

### BRIEF SUMMARY OF THE INVENTION

According to an aspect of the present invention, there is provided a method for manufacturing a semiconductor device comprising: forming a gate insulating film on a semiconductor substrate; and forming a gate electrode comprising a metal semiconductor compound layer and having a predetermined gate length on the gate insulating film, the forming the gate electrode including forming a polycrystalline semiconductor film having an average grain diameter equal to a specific size or less depending on the predetermined gate length and including at least one of silicon and germanium, the average grain diameter of the semiconductor film being 5 nm or more and 90 nm or less, forming a metal film on the semiconductor film; and converting whole of the semiconductor film into the metal semiconductor compound layer by reacting the semiconductor film and the metal film by heat treatment.

According to another aspect of the present invention, there is provided a method for manufacturing a semiconductor device comprising: forming a gate insulating film on a semiconductor substrate; and forming a gate electrode comprising a metal semiconductor compound layer and having a predetermined gate length on the gate insulating film, the forming the gate electrode including forming a polycrystalline semiconductor film having an average grain diameter equal to a specific size or less depending on the predetermined gate length and including at least one of silicon and germanium, amorphousizing at least a part of the semiconductor film; forming a metal film on the semiconductor film; and converting whole of the semiconductor film into the metal semiconductor compound layer by reacting the semiconductor film and the metal film by heat treatment.

### BRIEF DESCRIPTION OF THE SEVERAL VIEWS OF THE DRAWING

FIG. 1 is a cross-sectional view showing a sample comprising a silicon substrate and a nickel film;

FIG. 2 is a cross-sectional view for explaining silicide reaction of the sample of FIG. 1;

FIG. 3 is a cross-sectional view for explaining silicide reaction of the sample of FIG. 1 in case diffusion rate of Ni atoms is fast;

FIG. 4 is a cross-sectional view for explaining silicide reaction of the sample of FIG. 1 in case diffusion rate of Ni atoms is slow;

FIG. 5 is a cross-sectional view showing a sample comprising a silicon substrate, a gate oxide film, a polycrystalline silicon film larger in average grain diameter than 0.1 μm, and a nickel film;

FIG. 6 is a cross-sectional view for explaining silicide reaction of the sample of FIG. 5;

FIG. 7 is a cross-sectional view after silicide reaction of the sample of FIG. 5;

FIG. 8 is a cross-sectional view showing a sample comprising a silicon substrate, a gate oxide film, a polycrystalline silicon film in average grain diameter not larger than 0.1 μm, and a nickel film;

FIG. 9 is a cross-sectional view for explaining silicide reaction of the sample of FIG. 8;

FIG. 10 is a cross-sectional view after silicide reaction of the sample of FIG. 8;

FIG. 11 is a cross-sectional view showing another sample (third sample) comprising a silicon substrate, a gate oxide film, a polycrystalline silicon film in average grain diameter not larger than 0.1 μm, and a nickel film;

FIG. 12 is a cross-sectional view for explaining silicide reaction of the sample of FIG. 11;

FIG. 13 is a cross-sectional view after silicide reaction of the sample of FIG. 11;

FIG. 14 is a cross-sectional view showing a manufacturing process of a semiconductor device according to a second embodiment;

FIG. 15 is a cross-sectional view showing the manufacturing process of the semiconductor device according to the second embodiment following FIG. 14;

FIG. 16 is a cross-sectional view showing the manufacturing process of the semiconductor device according to the second embodiment following FIG. 15;

FIG. 17 is a cross-sectional view showing the manufacturing process of the semiconductor device according to the second embodiment following FIG. 16;

FIG. 18 is a cross-sectional view showing the manufacturing process of the semiconductor device according to the second embodiment following FIG. 17;

FIG. 19 is a cross-sectional view showing the manufacturing process of the semiconductor device according to the second embodiment following FIG. 18;

FIG. 20 is a cross-sectional view showing the manufacturing process of the semiconductor device according to the second embodiment following FIG. 19;

FIG. 21 is a view showing a cumulative frequency distribution of a sheet resistance value of a Ni silicide gate electrode (φ≧0.1 μm, φ=80 nm);

FIG. 22 is a cross-sectional view showing a manufacturing process of a semiconductor device according to a third embodiment;

FIG. 23 is a cross-sectional view showing the manufacturing process of the semiconductor device according to the third embodiment following FIG. 22;

FIG. 24 is a cross-sectional view showing the manufacturing process of the semiconductor device according to the third embodiment following FIG. 23;

FIG. 25 is a cross-sectional view showing the manufacturing process of the semiconductor device according to the third embodiment following FIG. 24;

FIG. 26 is a cross-sectional view showing a manufacturing process of a semiconductor device according to a fourth embodiment;

FIG. 27 is a cross-sectional view showing a manufacturing process of the semiconductor device according to the fourth embodiment following FIG. 26;

FIG. 28 is a cross-sectional view showing the manufacturing process of the semiconductor device according to the fourth embodiment following FIG. 27;

FIG. 29 is a cross-sectional view showing the manufacturing process of the semiconductor device according to the fourth embodiment following FIG. 28;

FIG. 30 is a cross-sectional view showing the manufacturing process of the semiconductor device according to the fourth embodiment following FIG. 29;

FIG. 31 is a cross-sectional view showing the manufacturing process of the semiconductor device according to the fourth embodiment following FIG. 30;

FIG. 32 is a cross-sectional view showing the manufacturing process of the semiconductor device according to the fourth embodiment following FIG. 31;

FIG. 33 is a view showing a relationship between a grain diameter of the polycrystalline silicon film and a thickness of the nickel silicide layer; and

FIG. 34 is a view showing a cumulative frequency distribution of the threshold voltage of an n-type MOS transistor (φ≧0.1 μm, φ=80 nm).

### DETAILED DESCRIPTION OF THE INVENTION

Embodiments of the present invention will be described with reference to the drawings.

(First Embodiment)

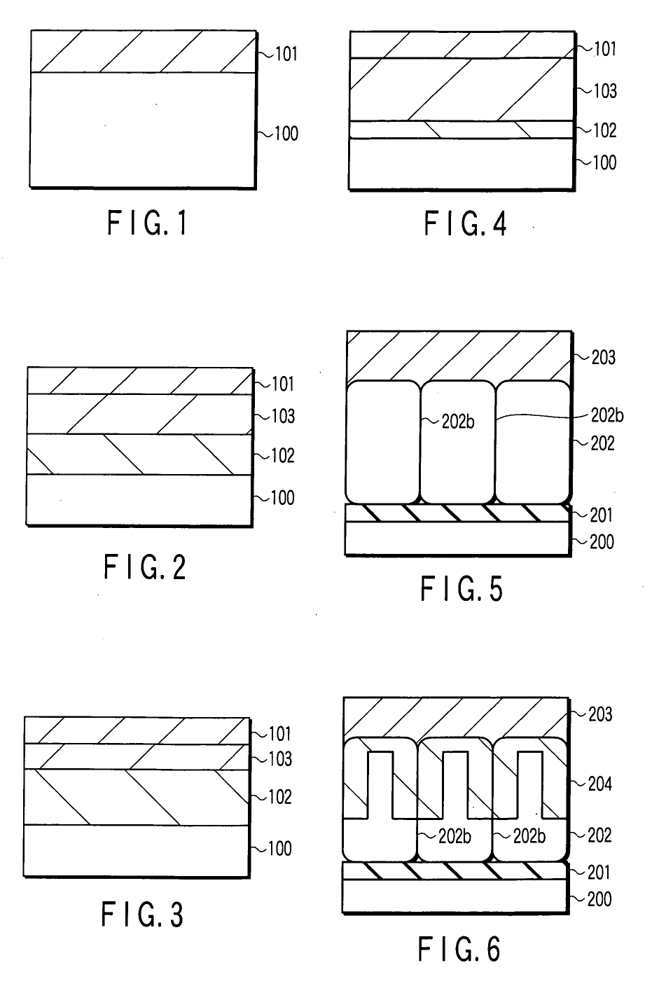

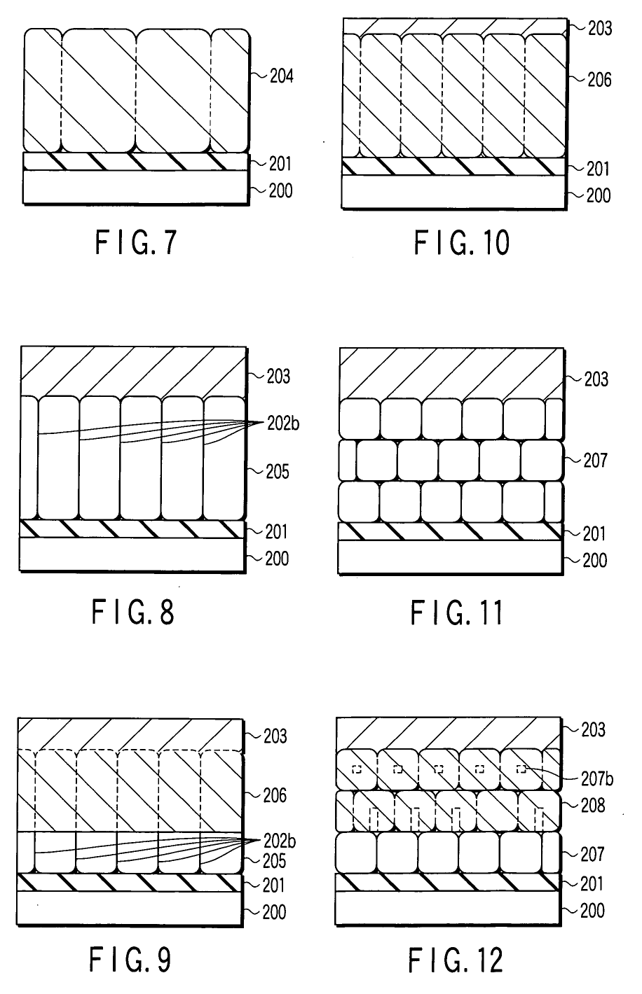

FIG. 1 shows a sample (a first sample) comprising a silicon substrate 100 and a nickel film 101 formed on the silicon substrate 100. By heating the first sample, the substrate 100 and the nickel film 101 react with each other, then, a silicide reaction progresses.

FIG. 2 shows a state of silicide reaction. It is said that the silicide reaction progresses while allowing the formation of a nickel monosilicide layer (hereinafter referred to as an NiSi layer) and a nickel silicide layer rich in nickel (hereinafter referred to as an Ni₂Si layer) 103.

In case a diffusion rate of Ni atoms is sufficiently fast, as shown in FIG. 3, the Ni₂Si layer 103 becomes thinner than the NiSi layer 102.

On the other hand, in case the diffusion rate of Ni atoms is slow, as shown in FIG. 4, the Ni₂Si layer 103 becomes thicker than the NiSi layer 102. In case the diffusion rate of Ni atoms is slow, before the NiSi layer 102 extends in the thickness direction of the silicon substrate 100 (downward the Figure), supply of the Ni atoms into the NiSi layer 102 proceeds. As a result, the Ni₂Si layer 103 becomes thicker than the NiSi layer 102.

Resistivity of the Ni₂Si layer 103 is 30 μΩcm, and resistivity of the NiSi layer 102 is 15 μΩcm. If the diffusion rate of the Ni atoms is slow, the Ni₂Si layer 103 becomes thicker than the NiSi layer 102, so that the sheet resistance becomes high.

FIG. 5 shows a sample (a second sample) comprising a silicon substrate 200, a gate oxide film 201 formed on the silicon substrate 200, a polycrystalline silicon film (gate electrode) 202 formed on the gate oxide film 201 and larger than 0.1 μm in average grain diameter, and a nickel film 203 formed on the polycrystalline silicon film 202. The grain diameter of the polycrystalline silicon film 202 can be measured by cross-section TEM for instance.

The polycrystalline silicon film 202 is formed by CVD process. Process conditions are, for example, a temperature of 600° C., a pressure of 66.6 Pa (0.5 torr), a source gas, and a flow ratio SiH₄/N₂=250/500 sccm.

Reference numeral 202b denotes a grain boundary in the polycrystalline silicon film 202. A crystal in the plolycrystal silicon film 202 is a column crystal. By heating the second sample, the polycrystalline silicon film 202 and the nickel film 203 react with each other, then, silicide reaction proceeds.

FIG. 6 shows a state in the midst of silicide reaction. While the Ni atoms diffuse the grain boundary 202b and crystal grains of the polycrystalline silicon film 202, the silicide reaction proceeds, so that a nickel silicide layer 204 is formed.

The diffusion of the Ni atoms in the polycrystalline silicon film 202 is dominant in grain boundary diffusion compared with the diffusion of the Ni atoms in the single crystal silicon substrate (bulk Si). The average grain diameter of the polycrystalline silicon film 202 is larger than 0.1 μm. In case the average grain diameter is larger than 0.1 μm, the rate of Ni atoms diffusing into the crystal grains is overwhelmingly slow compared with the rate of Ni atoms diffusing into the grain boundary. Therefore, the Ni atoms flowing into the grain boundary are relatively greater in number than the Ni atoms diffusing into the crystal grains.

Consequently, as shown in FIG. 7, in case all the polycrystalline silicon films 202 larger than 0.1 μm in average diameter are converted into Ni silicide layers 204, the ratio of the Ni₂Si layer in the Ni silicide layer 204 is higher than the ratio of the NiSi layer. As a result, the sheet resistance of the Ni silicide layer 204 becomes high.

FIG. 8 shows a sample (a third sample) comprising the silicon substrate 200, the gate oxide film 201 formed on the silicon substrate 200, a polycrystalline silicon film (gate electrode) 205 formed on the gate oxide film 201 and 0.1 μm or less in average grain diameter, and the nickel film 203 formed on the polycrystalline -silicon film 205. The grain diameter of the polycrystalline silicon film 205 can be measured, for example, by cross-sectional TEM.

The polycrystalline silicon film 205 is formed by CVD process. Process conditions are, for example, a temperature of 700° C., a pressure of 33330 Pa (250 torr), a source gas, and a flow ratio SiH₄/N₂=100/10000 sccm.

A crystal in the plolycrystal silicon film 205 is a column crystal. By heating the third sample, the polycrystalline silicon film 202 and the nickel film 203 react with each other, then, silicide reaction proceeds.

FIG. 9 shows a state in the midst of silicide reaction. While the Ni atoms diffuse the grain boundary 205b of the polycrystalline silicon film 205 and crystal grain, the silicide reaction proceeds, and then a Ni silicide layer 206 is formed.

The average grain diameter of the polycrystalline silicon film 205 is 0.1 μm or less. Hence, the diffusion of the Ni atoms in the polycrystalline silicon film 205 is not dominant in grain boundary diffusion.

The number of grain boundaries per unit volume in the polycrystalline silicon film 205 is greater in number than that in the polycrystalline silicon film 202 of the second sample. Hence, the number of Ni atoms diffusing in the crystal grains of the polycrystalline silicon film 205 is greater in number than that of the polycrystalline silicon film 202.

The size of the crystal grain in the polycrystalline silicon film 205 is smaller than that in the polycrysal silicon film 202 of the second sample. Hence, the Ni atoms in the polycrystalline silicon film 205 easily pass through within the crystal grains compared with the Ni atoms in the polycrystalline silicon film 202.

Consequently, as shown in FIG. 10, in case all the polycrystalline silicon film 205 which is 0.1 μm or less in average diameter are converted into Ni silicide layers 206, the ratio of the NiSi layer in the Ni silicide layer 206 is higher than the ratio of the Ni₂Si layer. As a result, the sheet resistance of the Ni silicide layer 204 is reduced, and fluctuation of the sheet resistance is controlled.

FIG. 11 shows a sample (fourth sample) comprising the silicon substrate 200, the gate oxide film 201 formed on the silicon substrate 200, a polycrystalline silicon film (gate electrode) 207 formed on the gate oxide film 201 which is 0.1 μm or less in average grain diameter, and the nickel film 203 formed on a polycrystalline silicon film 207. The crystal in the polycrystalline silicon film 207 is a granular crystal. By heating the fourth sample, the polycrystalline silicon film 207 and the nickel film 203 react with each other, then, the silicide reaction proceeds.

FIG. 12 shows a state in the midst of silicide reaction. While the Ni atoms diffuse a grain boundary 207b of the polycrystalline silicon film 207 and the crystal grain, the silicide reaction proceeds, so that a Ni silicide layer 208 is formed.

The fourth sample is 0.1 μm or less in average grain diameter of the polycrystalline silicon film 207. The fourth sample, similarly to the case of the third sample, compared with the second sample, is great in the number of grain boundaries per unit volume in the polycrystalline silicon film 207, and the number of Ni atoms diffusing the crystal grains of the polycrystalline silicon film 207 is large.

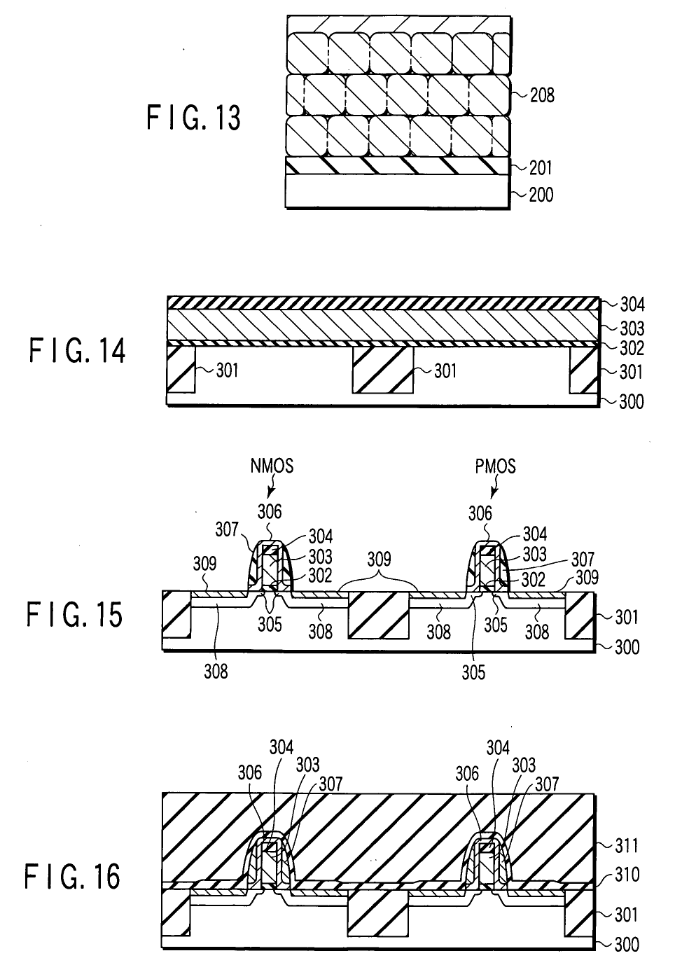

Consequently, as shown in FIG. 13, in case all the polycrystalline silicon film 207 which is 0.1 μm or less in average diameter are converted into the Ni silicide layers 208, similarly to the case of the third sample even in the case of the fourth sample, the sheet resistance of the Ni silicide layer 208 is reduced, and fluctuation of the sheet resistance is suppressed.

Here, in the fourth sample, since the crystal of the polycrystalline silicon film 207 is a granular crystal, the number of grain boundaries per volume unit of the polycrystalline silicon film 207 is greater in number than that of the polycrystalline silicon film 205 of the third sample. The crystal grain diameter of the polycrystalline silicon film 207 is smaller than that of the third sample. Hence, in the case of the fourth sample, the effect on the above described sheet resistance is further increased.

According to the study by the present inventors, it is found out that the following facts are the reasons why fluctuation in the sheet resistance of the metal silicide gate electrode becomes remarkable particularly in the case of the fine pattern. The facts are as follow. The dominant diffusion path (crystal grain, grain boundary) of the metal varies depending on the difference of the average grain diameter of the polycrystalline silicon film (polycrystalline silicon gate electrode). The diffusion coefficient of the metal varies depending on the difference of the diffusion path. The composition of the metal silicide layer to be formed varies depending on the diffusion coefficient. And then, the resistance of the metal silicide layer varies depending on the difference of the composition.

Consequently, By siliciding the polycrystalline semiconductor film having an average grain diameter (5 to 90 nm is appropriate as described in second embodiment) not less than a predetermined size depending on a gate length is silicidized, the sheet resistance can be reduced, and fluctuation in the sheet resistance can be suppressed.

Further, since the silicide electrode is a metal gate electrode, a threshold voltage of the transistor is decided by work function of the silicide layer. If the composition of the silicide layer varies, its work function also spontaneously varies. For example, while the work function of NiSi is 4.5 eV, the work function of Ni₂Si is 4.7 eV. Therefore, if a composition ratio of the silicide electrode fluctuates, the threshold voltage of the transistor also fluctuates.

Hence, by applying the present embodiment to the transistor, not only the fluctuation of the sheet resistance but also the threshold voltage can be reduced.

(Second Embodiment)

FIGS. 14 to 20 are cross-sectional views showing a manufacturing process of a semiconductor device according to a second embodiment. The present embodiment is an example in which the method of forming the Ni silicide layer described in the first embodiment is applied to the forming process of the gate electrodes of MIS type transistors of a CMOS circuit in a logic circuit. The present embodiment corresponds to the device subsequent to 0.1 μm generation.

[FIG. 14]

An isolation area 301 is formed on a surface of a silicon substrate 300 of single crystal by shallow trench isolation (STI) process. A gate insulating film 302 is formed on the silicon substrate 300. Here, the gate insulating film 302 is a silicon oxynitride film. When the film thickness of the silicon oxynitride film is converted into an equivalent oxide thickness of the gate oxide film, it is, for example, approximately 1.2 nm. A polycrystalline silicon film 303 which is 0.1 μm or less in average crystal grain diameter is formed on the gate insulating film 302. Here, the film thickness of the polycrystalline silicon film 303 is 100 nm. A silicon nitride film 304 is formed on the polycrsytal silicon film 303. The method for forming the polycrystalline silicon film 0.1 μm or less in average crystal grain diameter is, for example, as described in the first embodiment.

[FIG. 15]

The silicon nitride film 304, the polycrystalline silicon film 303, and the gate insulating film 302 are processed by lithography process and anisotropic etching process, thereby gates 302 to 304 of the predetermined shape is obtained. The gate length thereof is, for example, approximately 60 nm. In FIG. 15 is shown the gates 302 to 304 of an n-channel MOS transistor (NMOS) and a p-channel MOS transistor (PMOS).

By using the NMOS gates 302 to 304 and an unillustrated resist as a mask, N type impurity ions (for example As⁺ ion) are implanted into an active area of the NMOS by ion implantation process. Similarly, by using the gates 302 to 304 of the PMOS and an unillustrated resist as a mask, P type impurity ions (for example B⁺ ion) are implanted into an active area of the PMOS by ion implantation process. By annealing process at 800° C. for five seconds, the N and P type impurity ions are activated, so that extensions (shallow diffusion layer) 305 are formed.

The side surfaces of the gates 302 to 304 are surrounded by a spacer including the silicon oxide film 306 and the silicon nitride film 307. The forming process of the spacer includes a process of depositing the silicon oxide film 306 and the silicon nitride film 307, and a process of etchbacking the silicon oxide film 306 and the silicon nitride film 307.

By using the spacers 306 and 307 and an unillustrated resist as a mask, N type impurity ions (for example P⁺ ion) are implanted into an active area of the NMOS by ion implantation process. Similarly, by using the spaces 306 and 307 and an unillustrated resist as a mask, P type impurity ions (for example B⁺ ion) are implanted into an active area of the PMOS by ion implantation process. By annealing process at 1030° C. for five seconds, the N and P type impurity ions are activated, so that source/drain regions 308 are formed.

Ni silicide layers 309 are formed on the surfaces of the source/drain regions 308. The forming process of the Ni silicide layer 309 includes a process of depositing an unillustrated nickel film on the entire surface, a process of allowing the nickel film and the surface of the source/drain region 308 (silicon area) to react with each other by performing heat treatment to the extent of 350° C. for 30 sec, a process of removing an unreacted nickel film, and a process of performing heat treatment to the extent of 500° C. for 30 sec. The film thickness of the nickel film is, for example, 10 nm. The removal of the unreacted nickel film is performed, for example, by a wet process using a mixed liquid of sulfuric acid and hydrogen peroxide solution.

[FIG. 16]

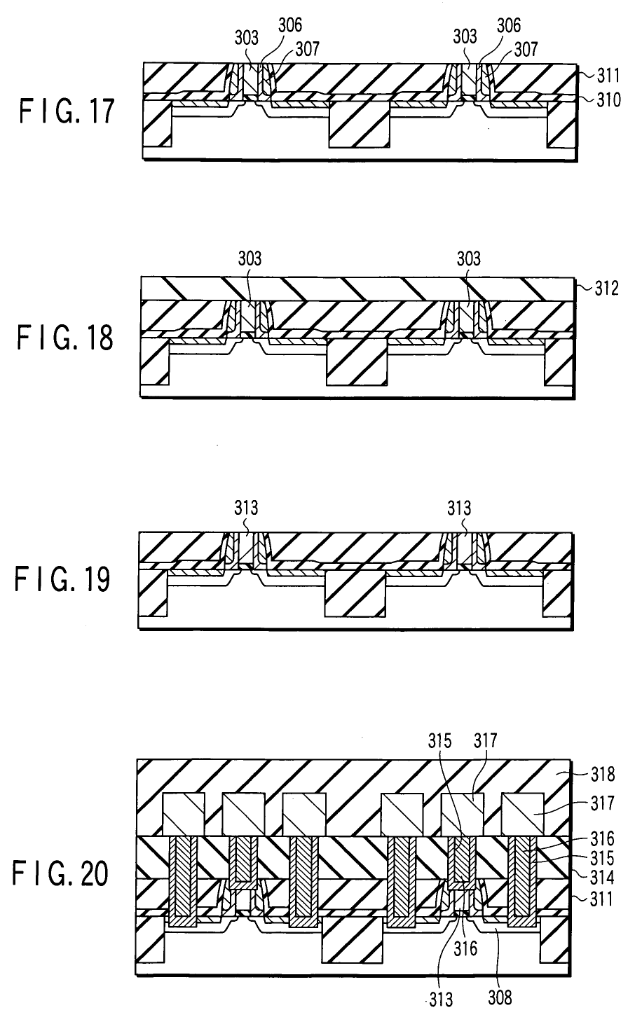

A silicon nitride film 310 is deposited on the entire surface. The film thickness of the silicon nitride film 310 is, for example, 30 nm. An interlayer insulating film 311 is deposited on the silicon nitride film 310. The film thickness of the interlayer insulating film 311 is, for example, 250 nm.

[FIG. 17]

The interlayer insulating film 311 is polished by CMP process until the surface of the silicon nitride film 310 is exposed, so that the surface is planarized. Further, the interlayer insulating film 311, the silicon nitride film 310 on the polycrystalline silicon film (polysilicon gate electrode) 303, the silicon oxide film 306, and the silicon nitride film 304 are removed by etchback until the surface (top face) of the polycrystalline silicon film 303 is exposed, so that the surface is planarized. The surface (top face) of the polycrystalline silicon film 303 is exposed. It does not matte if the planarizing is performed only by CMP process without using etchback together.

[FIG. 18]

A nickel film 312 is formed on the area including the polycrystalline silicon film 303. Here, the polycrystalline silicon film 303 is formed on the entire surface. The film thickness of the nickel film 312 is, for example, 40 nm.

[FIG. 19]

The nickel film 312 and the polycrystalline silicon film 303 are reacted with each other by the heat treatment, and the polycrystalline silicon film 303 is converted into the Ni silicide film. As a result, a Ni silicide gate electrode 313 is formed. The unreacted nickel film 312 is removed.

In the reaction between Ni and Si, the diffusion coefficient of Ni is large than that of Si. Hence, a thickness of reaction layer with Ni and Si is almost decided by diffusion of the Ni atoms into the polycrystalline silicon film 303 from the nickel film 312. The Ni atoms in the nickel film 312 on the top face of the polycrystalline silicon film 303 diffuse into the polycrystalline silicon film 303. Further, the Ni atoms in the nickel film 312 on the periphery of the top face of the polycrystalline silicon film 303 also diffuse into the polycrystalline silicon film 303. At this time, the Ni atoms diffuse into the polycrystalline silicon film 303 from the periphery of the top face of the polycrystalline silicon film 303 as if coming in avalanche.

A silicide reaction rate changes depending not only on the diffusion coefficient of Ni and Si, but also on the impurities included in the polycrysal silicon film 303. The reason is said that the impurities are segregated at an interface of silicide and silicon, and the segregated impurities disturb the silicide reaction.

In the present embodiment, the polycrystalline silicon film 303 which is 0.1 μm or less in crystal grain diameter is formed (FIG. 14). Hence, the diffusion of the Ni atoms into the polycrystalline silicon film 303 and its reaction are expedited. Thereby, a uniform NiSi layer comprising fine crystals is formed. As a result, the resistance of the Ni silicide gate electrode 313 is reduced, and fluctuation of its resistance is suppressed.

At first sight, in the process of FIG. 14, it seems that the forming of the silicon film in an amorphous state offers promising prospects, but, in reality, it does not. The reason is as follows.

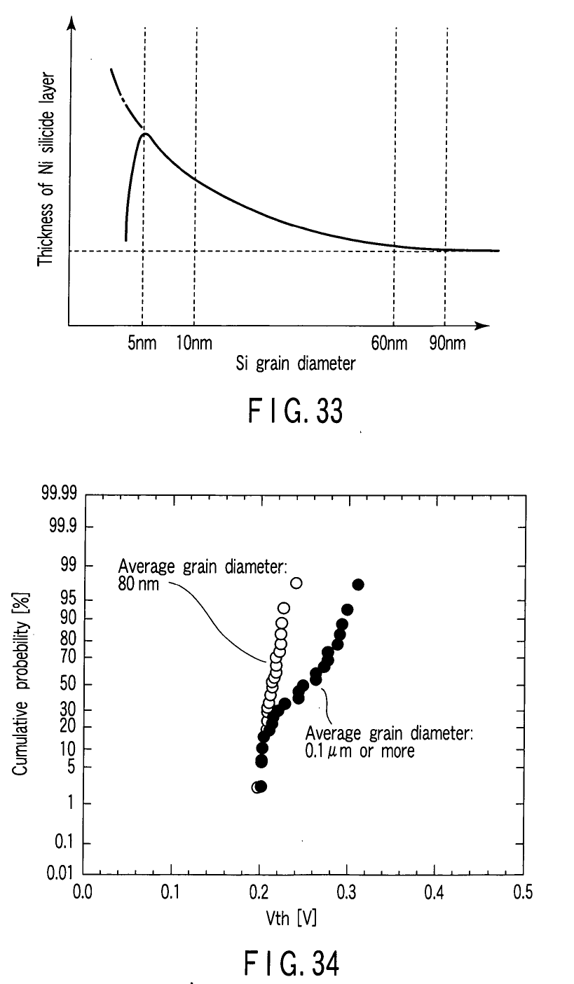

FIG. 33 shows a relationship between the grain diameter of the polycrystalline silicon film 202 and the thickness of the nickel silicide layer 204. Incidentally, the thickness of the nickel silicide layer 204 is defined as a thickness of the Ni siliside layer (reaction layer) uniformly formed, and the reaction layer formed locally in the grain boundary is excluded.

As shown in FIG. 33, the thickness of the Ni silicide layer 204 depends on the grain diameter of the polycrystalline silicon film 202, and if the average grain diameter is reduced 90 nm or less, the thickness of the nickel silicide layer 204 begins to increase.

However, when the average grain diameter is reduced below 5 nm, in contrast to this, the thickness of the nickel silicide layer 204 becomes thin. That is, it is well-known that if it is amorphous, the reaction thereof is easily promoted, however, as described above, since the heat treatment for forming the diffusion layer is added, it is difficult to maintain the amorphous state at the forming time of the nickel silicide layer 204. Even if it is possible to form the silicon film 5 nm or less in average grain diameter including amorphous, due to solid phase growth by post-heat process, the average grain diameter increases at a point of time before forming the nickel film 203.

Hence, if the average grain diameter is not 5 nm or more, it is not possible to maintain a fine crystal state after the post-heat process. That is, whether the crystal grain diameter is too small or too large, there is no hope of uniform reaction with Ni and Si. Hence, it is desirable that the average grain diameter of the polycrystalline silicon film 202 is in the range of 5 nm or more and 90 nm or less.

Further, while the experiment of FIG. 33 does not introduce impurities into the polycrystalline silicon film 202, in case P (phosphor) is introduced into the polycrystalline silicon film 202, it is known that the crystal grain diameter after post-heat process becomes larger, compared with the case where P (phosphor) is not introduced. When consideration is given to the crystal grain growth by these impurities, it is desirable that the average grain diameter of the polycrystalline silicon film 202 is in the range of 10 nm or more and 60 nm or less.

That is, it is well-known that, if it is amorphous, the reaction is easily advanced, but, as described above, because of the addition of heat treatment for forming the diffusion layer, it is difficult to maintain the amorphous state at the NiSi reaction layer forming time. Even if it is possible to form the silicon film 5 nm or less in average grain diameter including amorphous, due to solid phase growth by the post-heat process, the grain diameter increases greatly in size at a point of time before forming the Ni film, and unless the average grain diameter is 5 nm or more, it is not possible to maintain the fine crystal state after post-heat process. Thus, whether the crystal grain diameter is too small or too large, there is no hope of a uniform reaction to Ni. It is, therefore, desirable that the average grain size of the Poly-Si film is in the range of 5 nm to 90 nm. In addition, the present experiment does not introduce impurities at all into the silicon film, however, in case P is introduced into the silicon film, it is known that the crystal grain diameter after post-heat process becomes large, compared with the case where P is not introduced. When consideration is given to the crystal grain growth by these impurities, it is desirable that the average grain diameter of the Poly-Si film is 10 nm to 60 nm.

In the process of FIG. 15, annealing process (heat treatment) for forming the diffusion layers (extensions and source/drain regions) 305 and 308 is performed. By the annealing process at this time, the silicon film is unable to maintain an amorphous state. In the silicon film becoming unable to maintain the amorphous state, there arise giant crystal grains.

The giant crystal grains suppress the silicide reaction.

[FIG. 20]

An interlayer insulating film 314 is formed on the entire surface. A contact hole for the source/drain region 308 and a contact hole for the Ni silicide gate electrodes 313 are formed in the interlayer insulating films 311 and 314.

The inside of the contact hole is embedded with contacts (barrier metal 315 and plug 316). The barrier metal 315 is, for example, Ti/TiN. The plug 316 is, for example, a W (tungsten) plug.

The forming process of the barrier metal 315 and the plug 316 includes, for example, a process of embedding the inside of the contact hole with the Ti film, the TiN film, and the W film, and a process of removing excessive Ti film, TiN film, and W film and planarizing the surface by CMP process

A metal wiring 317 for electrically connecting the contact holes 315 and 316 are formed. The metal wiring 317 is, for example, an AI wiring (TiN/AI/Ti wiring) or a Cu damascene wiring.

An interlayer insulating film 318 is formed on the entire surface. The interlayer insulating film 318 is planarized by CMP process.

By the above described processes, the CMOS circuit comprising the MIS type transistors including the Ni silicide gate electrodes 313 low in resistance and little in fluctuation can be realized.

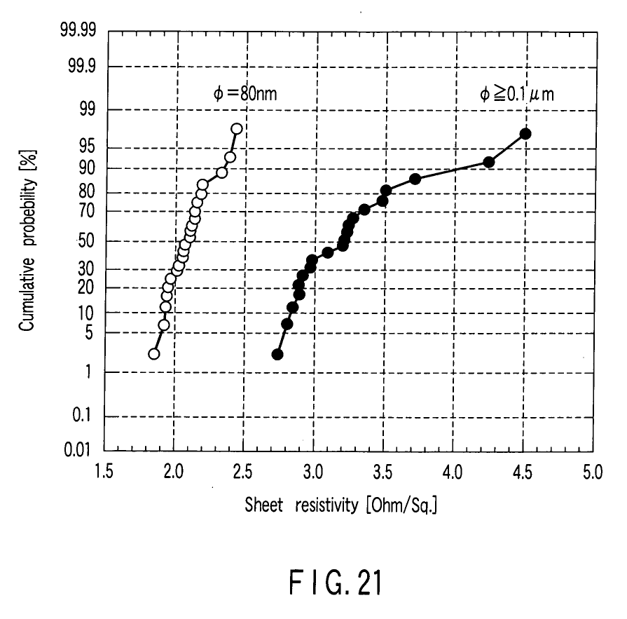

FIG. 21 shows a cumulative frequency distribution of the sheet resistance value of the Ni silicide gate electrode. In the Figure, a white circle shows the case where the average crystal grain diameter φ of the polycrystalline silicon film which becomes the Ni silicide gate electrode is not less than 0.1 μm (φ≧0.1 μm), and a black circle shows the case where the average crystal grain diameter is 80 nm (φ=80 nm). By comparing both cases, in the case of φ=80 nm (embodiment), it is found that, compared with the case of φ≧0.1 μm (conventional case), the sheet resistance and its fluctuation are sufficiently small. It is thus verified that Ni silicidation reaction is expedited by controlling the crystal grain diameter of the silicon film.

FIG. 34 shows a cumulative frequency distribution of the threshold voltage (Vth) of the n-type MOS transistor. The gate length is 60 nm. In case the average crystal grain diameter φ is 80 nm, it is found that, compared with the case where the average crystal grain diameter is 0.1 μm or more, fluctuation of the threshold voltage (Vth) is small. With fluctuation of the composition of the silicide electrode reduced, it is possible to control the threshold voltage of the transistor, which is the most important issue of the metal electrode.

In the present embodiment, the polycrystalline silicon film is used as a semiconductor film to be the gate electrode (metal semiconductor compound layer), other semiconductor films may be used. For example, a silicon germanium film or a germanium film may be used. In the former case, a part or the whole of the silicon in the silicon germanium film is silicized.

In the present embodiment, Ni is used as a metal (refractory metal) of metal silicide, it does not matter using Er, Tm, Pd, Pt, Co, Rh, Ir, W, Mo, compound of these refractory metals, and furthermore, substance including at least two materials from among these refractory metals and compounds thereof.

In the present embodiment, the nickel monosilicide (NiSi) layer is used as the metal silicide layer, a Pt₂Si layer, a PtSi layer, a Pd₂Si layer, a PdSi layer, a Co₂Si layer, a CoSi layer, a CoSi₂ layer, an ErSi layer, an ErSi_{1.7} layer, a TmSi layer, and the like may be used.

In the present embodiment, the metal silicide layer on the gate electrode and the metal silicide layer on the diffusion layer is the same metal silicid layer (Ni silicide layer), it does not matter if these are different metal silicide layers.

In the present embodiment, the silicon oxynitride film is used as the gate insulating film, it does not matter if the silicon oxide film or the silicon nitride film is used. Although there is no limit to the method of forming these insulating films, as a representative forming method, a thermally-oxynitride, CVD process, and the like can be cited.

Further, the gate insulating film is not limited to the silicon system oxide film, but the high-k film may be used. For example, the insulating film including oxide of Hf, Zr, Ti, Ta, Al, Sr, Y or La, or oxide of one of the elements and Si (for example, ZrSixOy) may be used. Further, a laminated layer of these insulating films may be used.

(Third Embodiment)

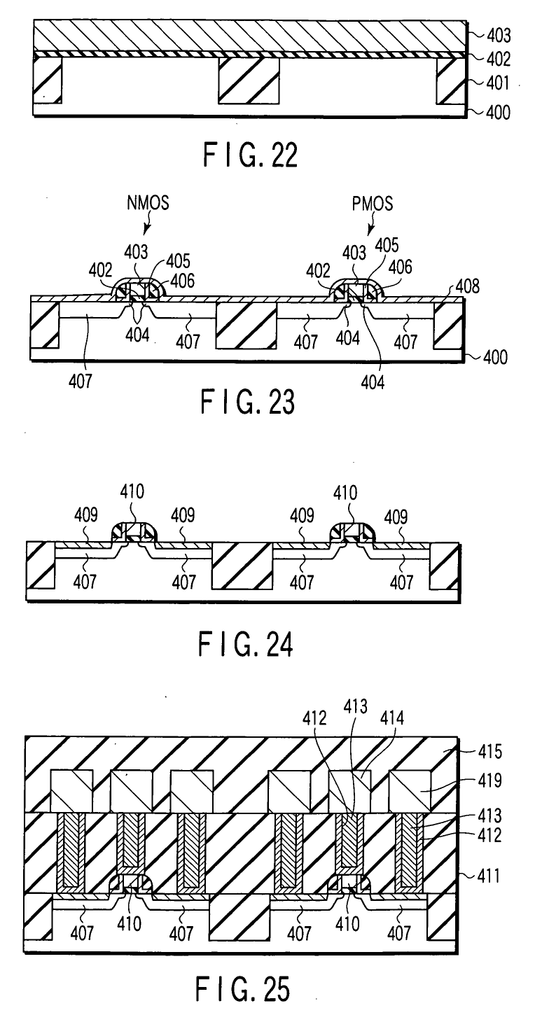

FIGS. 22 to 25 are cross-sectional views showing a process of manufacturing a semiconductor device according to a third embodiment. The present embodiment is an example in which the method of forming the Ni silicide layer described in the first embodiment is applied to the forming process of the gate electrodes of MIS type transistors of a CMOS circuit in a logic circuit. In the present embodiment, silicidation of the surface of a source/drain regions and silicidation of a polysilicon gate electrode are simultaneously performed. The present embodiment corresponds to the device subsequent to 0.1 μm generation.

[FIG. 22]

An isolation area 401 is formed on a surface of a silicon substrate 400 of single crystal by STI process. A gate insulating film 402 is formed on the silicon substrate 400. Here, the gate insulating film 402 is a silicon oxynitride film. When the film thickness of the silicon oxynitride film is converted into an equivalent oxide thickness of the gate oxide film, it is, for example, approximately 1.2 nm. A polycrystalline silicon film 403 which is 0.1 μm or less in average crystal grain diameter is formed on the gate insulating film 402. Here, the film thickness of the polycrystalline silicon film 403 is 30 nm.

[FIG. 23]

The polycrystalline silicon film 403 and the gate insulating film 402 are processed by lithography process and anisotropic etching process, then, gates 402 and 403 of the predetermined shape are obtained. The gate length thereof is, for example, approximately 60 nm. FIG. 23 shows the gates 402 and 403 of NMOS and PMOS.

By using the gates 402 and 403 of the NMOS and an unillustrated resist as a mask, N type impurity ions (for example As⁺ ion) are implanted into an active area of the NMOS by ion implantation process. Similarly, by using the gates 402 and 403 of the PMOS and an unillustrated resist as a mask, P type impurity ions (for example B⁺ ion) are implanted into an active area of the PMOS by ion implantation process. By annealing process at 800° C. for five seconds, the N and P type impurity ions are activated, so that an extensions (shallow diffusion layers) 404 are formed.

The side surfaces of the gates 402 and 403 are surrounded by a spacer including the silicon oxide film 405 and the silicon nitride film 406. The forming process of the spacer includes a process of depositing the silicon oxide film 405 and the silicon nitride film 406, and a process of etchbacking the silicon oxide film 405 and the silicon nitride film 406.

By using the spacers 405 and 406 of NMOS and an unillustrated resist as a mask, N type impurity ions (for example P⁺ ion) are implanted into an active area of the NMOS by ion implantation process. Similarly, by using the spaces 405 and 406 of PMOS and an unillustrated resist as a mask, P type impurity ions (for example B⁺ ion) are implanted into an active area of the PMOS by ion implantation process. By the annealing process at 1030° C. for five seconds, the N and P type impurity ions are activated, so that a source/drain region 407 is formed.

The nickel film 408 is formed on the entire surface. The film thickness of the nickel film 408 is, for example, 15 nm.

[FIG. 24]

A Ni silicide layer 409 is formed on the surface of source/drain regions 407, and the polycrystalline silicon film 403 is converted into a Ni silicide gate electrode 410.

The method of forming the Ni silicide layer 409 and the Ni silicide gate electrode 410 includes a process of allowing the nickel film 408 and the surface of the source/drain regions 407 to react with each other by performing a heat treatment approximately at 350° C. for 30 sec, and a process of allowing the nickel film 408 and the polycrystalline silicon film 403 to react with each other, a process of removing an unreacted nickel film 408, and further, a process of performing the heat treatment approximately at 500° C. for 30 sec. The removal of the unreacted nickel film 408 is, for example, performed by a wet process using a mixed liquid of sulfuric acid and hydrogen peroxide solution.

Since the polycrystalline silicon film (polysilicon gate electrode) 403 is thin (film thickness 30 nm), all the polycrystalline silicon films 403 is converted into the Ni silicide layers by the above described process.

The film thickness of the polycrystalline silicon film 403 immediately after its formation not necessarily needs to be thin. After forming the polycrystalline silicon film 403, it does not matter if the polycrystalline silicon film 403 is made thin. For example, the polycrystalline silicon film 403 is formed, for example, by the thickness of 100 nm, and after that, until before forming the nickel film 408, the polycrystalline silicon film 403 is made thinner, for example, to the extent of 30 nm by the method such as the etchback and the like.

Silicidation of the surface of the source/drain regions 407 and silicidataion of the polycrystalline silicon film 403 are simultaneously performed. A film thickness allowed for the polycrystalline silicon film 403 changes depending on the thickness of the Ni silicide layer 409 (design film thickness). In case the Ni silicide layer 409 is thin, the polycrystalline silicon film 403 also needs to be thin. When the polycrystalline silicon film 403 is thick, the entirety of the polycrystalline silicon film 403 is not converted into the Ni silicide layer. That is, the film thickness of the polycrystalline silicon film 403 needs to be linked with the design film thickness of the Ni silicide layer 409. In case the Ni silicide layer 409 is thick, the polycrystalline silicon film 403 can be made thick as well as thin.

[FIG. 25]

An interlayer insulating film 411 is formed on the entire surface. A contact hole for the source/drain region 407 and a contact hole for the Ni silicide gate electrode 410 are formed in the interlayer insulating film 411.

The inside of the contact hole is embedded with contact (barrier metal 412 and plug 413). The barrier metal 412 is, for example, Ti/TiN. The plug 413 is, for example, a W (tungsten) plug.

The forming process of the barrier metal 412 and the plug 413 includes, for example, a process of embedding the inside of the contact hole with the Ti film, the TiN film, and the W film, and a process of removing excessive Ti film, TiN film, and W film and planarizing the surface by CMP process.

A metal wiring 414 for electrically connecting the contacts 412 and 413 are formed. The metal wiring 414 is, for example, an Al wiring (TiN/Al/Ti wiring) or a Cu damascene wiring.

An interlayer insulating film 415 is formed on the entire surface. The interlayer insulating film 415 is planarized by CMP process.

By the above described processes, the CMOS comprising the MIS type transistor including the Ni silicide gate electrode 410 low in resistance and small in fluctuation, and capable of controlling fluctuation of the threshold voltage of the transistor can be realized.

With respect to the semiconductor film to be the gate electrode, the metal of the metal silicide, the metal silicide layer, the metal silicide layer on the gate electrode and the metal silicide layer on the diffusion layer, and the gate insulating film, the same modified example as the second embodiment is possible.

(Fourth Embodiment)

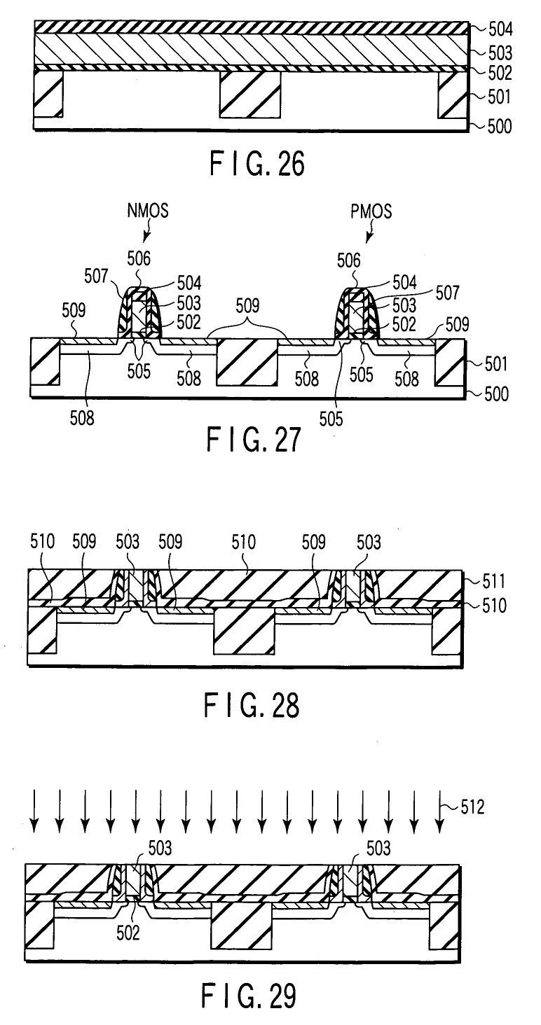

FIGS. 26 to 32 are cross-sectional views showing a manufacturing process of a semiconductor device according to a fourth embodiment. The present embodiment is an example in which the method of forming the Ni silicide layer described in the first embodiment is applied to the forming process of the gate electrode of a MIS type-transistor of a CMOS circuit. In the present embodiment, after source/drain regions are formed, at least a part of a polysilicon gate electrode is amorphousized. This amorphous polysilicon gate electrode is converted into a Ni silicide gate electrode. The present embodiment corresponds to the device subsequent to 0.1 μm (for example, 60 nm) generation.

[FIG. 26]

An isolation area 501 is formed on a surface of a silicon substrate 500 of single crystal by STI process. A gate insulating film 502 is formed on the silicon substrate 500. Here, the gate insulating film 502 is a silicon oxynitride film. When the film thickness of the silicon oxynitride film is converted into an equivalent oxide thickness of the gate oxide film, it is, for example, approximately 1.2 nm. A polycrystalline silicon film 503 which is 0.1 μm or less in average crystal grain diameter is formed on the gate insulating film 502. Here, the film thickness of the polycrystalline silicon film 503 is 100 nm. A silicon nitride film 504 is formed on the silicon film 503.

[FIG. 27]

The silicon nitride film 504, silicon film 503 and the gate insulating film 502 are processed by lithography process and anisotropic etching process, thereby gates 502 to 504 having a predetermined shape are obtained. The gate length is, for example, approximately 60 nm. FIG. 27 shows the gates 502 to 504 of NMOS and PMOS.

By using the gates 502 to 504 of the NMOS and an unillustrated resist as a mask, N type impurity ions (for example As⁺ ion) are implanted into an active area of the NMOS by ion implantation process. Similarly, by using the gates 502 to 504 of the PMOS and an unillustrated resist as a mask, P type impurity ions (for example B⁺ ion) are implanted into an active area of the PMOS by ion implantation process. By annealing process at 800° C. for five seconds, the N and P type impurity ions are activated, so that an extensions (shallow diffusion layers) 505 are formed.

The side surfaces of the gates 502 to 504 are surrounded by a spacer including the silicon oxide film 506 and the silicon nitride film 507. The forming process of the spacer includes a process of depositing the silicon oxide film 506 and the silicon nitride film 507, and a process of etchbacking the silicon oxide film 506 and the silicon nitride film 507.

By using the spacers 506 and 507 of the NMOS and an unillustrated resist as a mask, N type impurity ions (for example P⁺ ion) are implanted into an active area of the NMOS by ion implantation process. Similarly, by using the spacers 506 and 507 of PMOS and an unillustrated resist as a mask, P type impurity ions (for example B⁺ ion) are implanted into an active area of the PMOS by ion implantation process. By annealing process at 1030° C. for five seconds, the N and P type impurity ions are activated, so that source/drain regions 508 are formed.

A Ni silicide layer 509 are formed on the surface of the source/drain regions 508. The forming process of the Ni silicide layers 509 includes a process of depositing an unillustrated nickel film on the entire surface, a process of allowing the nickel film and the surface of the source/drain regions 508 (silicon areas) to react with each other by performing heat treatment to the extent of 350° C. for 30 sec, a process of removing an unreacted nickel film, and a process of performing heat treatment to the extent of 500° C. for 30 sec. The film thickness of the nickel film is, for example, 10 nm. The removal of the unreacted nickel film is performed, for example, by wet process using a mixed liquid of sulfuric acid and hydrogen peroxide solution.

[FIG. 28]

A silicon nitride film 510 is deposited on the entire surface. The film thickness of the silicon oxynitride 510 is, for example, 30 nm. An interlayer insulating film 511 is deposited on the silicon nitride film 510. The film thickness of the interlayer insulating film 511 is, for example, 250 nm.

The interlayer insulating film 511 is polished by CMP process until the surface of the silicon nitride film 510 is exposed, so that the surface is planarized. Further, the interlayer insulating film 511, the silicon nitride film 504 on the silicon film (polysilicon gate electrode) 503, the silicon oxide film 506, and the silicon nitride film 507 are removed by etchback until the surface (top face) of the silicon film 503 is exposed, so that the surface is planarized. It does not matte if the planarizing is performed only by CMP process without using the etchback together.

[FIG. 29]

By ion implantation process, Ge ions 512 are implanted into the polycrystalline silicon film 503. As a result, an amorphousized silicon film 503 is obtained.

When an attempt is made at amorphousization of the polycrystalline silicon film 503 up to the vicinity of the gate insulating film 502, there is the possibility that the gate insulating film 502 suffers damage. Hence, in the present embodiment, the surface layer only of the silicon film (polysilicon gate electrode) 503 is amorphousized. In a case where thickness of the silicon film 503 is 100 nm, injection conditions of the Ge ions is, for example, an accelerating voltage of 90 Kev and a dose amount of 5×10¹⁵ cm⁻² or more. It is possible to amorphousize all of the silicon film 503.

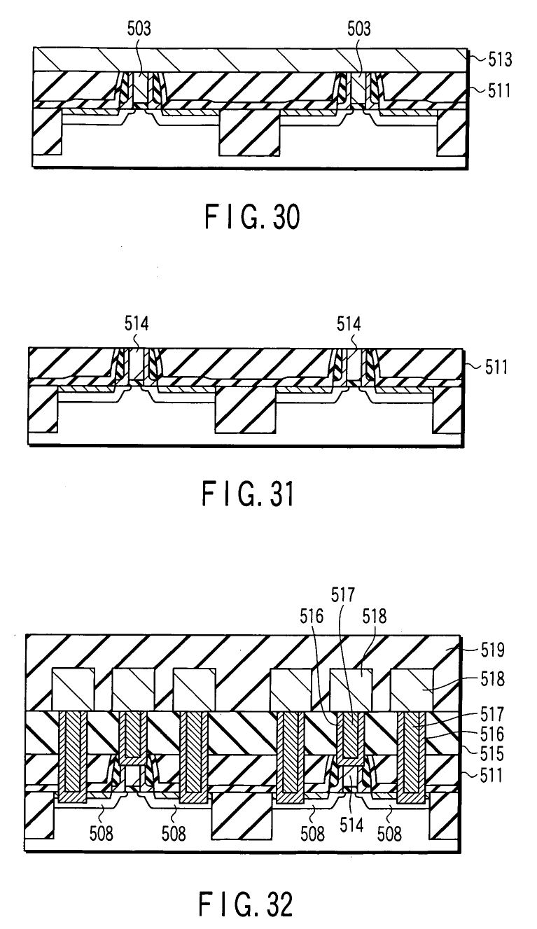

To amorphousize the silicon film 503, inert elements such as He, Ne, Ar, Kr, and the like, Si ions and impurities ions such as Ga or As, and the like may be implanted into the silicon film 503 in place of the Ge Ion 512.

[FIG. 30]

A nickel film 513 is formed on the area including the amorphousized silicon film. Here, the nickel film 513 is formed on the entire surface. The film thickness of the nickel film 513 is, for example, 40 nm.

[FIG. 31]

The nickel film 513 and the silicon film are reacted with each other by heat treatment, so that the silicon film is converted into a Ni silicide film. As a result, a Ni silicide gate electrode 514 is formed. An unreacted nickel film 513 is removed.

In the reaction between Ni and Si, the diffusion coefficient of Ni is large compared with that of Si. Hence, a thickness of reaction layer with Ni and Si is mostly decided by diffusion of Ni atoms into the silicon film 503 from the nickel film 513. The Ni atoms in the nickel film 513 on the top face of the silicon film 503 diffuse into the silicon film 503. Further, the Ni atoms in the nickel film 513 on the surface periphery of the top face of the silicon film 503 also diffuse into the silicon film. At this time, the Ni atoms diffuse into the silicon film 503 from the periphery of the top face of the polycrystalline silicon film 503 as if coming in avalanche.

The silicon film 503 is amorphousized. Hence, compared to the polycrystalline silicon film, the diffusion of the Ni atoms into the silicon film 503 and its reaction are expedited. Thereby, a uniform NiSi layer comprising fine crystal is formed. As a result, the resistance of a Ni silicide gate electrode 514 is reduced, and fluctuation of its resistance is suppressed.

In the present embodiment, only the surface layer of the silicon film 503 is amorphousized. Hence, a silicide reaction is sufficiently expedited on the surface layer of the silicon film 503, however, the silicide reaction at other than the surface layer is not sufficiently expedited. However, since the average crystal grain diameter of the silicon film 503 is 0.1 μm or less, the silicide reaction is sufficiently expedited in the whole of the silicon film 503.

[FIG. 32]

An interlayer insulating film 515 is formed on the entire surface. Contact holes for the source/drain regions 508 and Contact holes for the Ni silicide gate electrode 514 are formed in the interlayer insulating films 511 and 515.

The inside of the contact hole is embedded with contacts (barrier metal 515 and plug 516). The barrier metal 515 is, for example, Ti/TiN. The plug 516 is, for example, a W (tungsten) plug.

The forming process of the barrier metal 515 and the plug 516 includes, for example, a process of embedding the inside of the contact hole with the Ti film, the TiN film, and the W film, and a process of removing excessive Ti film, TiN film, and W film and planarizing the surface by CMP process.

A metal wiring 517 for electrically connecting the contact holes 515 and 516 are formed. The metal wiring 517 is, for example, an Al wiring (TiN/Al/Ti wiring) or a Cu damascene wiring.

An interlayer insulating film 518 is deposited on the entire surface. The interlayer insulating film 518 is planarized by CMP process.

By the above described processes, the CMOS comprising the MIS type transistor including the Ni silicide gate electrode 514 low in resistance and small in fluctuation, and capable of controlling fluctuation of the threshold voltage of the transistor can be realized.

With respect to the semiconductor film to be a gate electrode, the metal of the metal silicide, the metal silicide layer, the metal silicide layer on the gate electrode and-the metal silicide layer on the diffusion layer, and the gate insulating film, the same modified example as the second embodiment is possible.

Incidentally, the present invention is not limited to the above described embodiments. For example, in the above described embodiments, the silicon substrate has been used, a SIO substrate and a substrate containing SiGe in the active area may be used. The present invention is applicable also to the transistor other than the MIS type transistor of the CMOS circuit.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for manufacturing a semiconductor device comprising:
forming a gate insulating film on a semiconductor substrate; and
forming a gate electrode comprising a metal semiconductor compound layer and having a predetermined gate length on the gate insulating film, the forming the gate electrode including forming a polycrystalline semiconductor film having an average grain diameter equal to a specific size or less depending on the predetermined gate length and including at least one of silicon and germanium, the average grain diameter of the semiconductor film being 5 nm or more and 90 nm or less, forming a metal film on the semiconductor film; and converting whole of the semiconductor film into the metal semiconductor compound layer by reacting the semiconductor film and the metal film by heat treatment.

2. A method for manufacturing the semiconductor device comprising:
forming a gate insulating film on a semiconductor substrate; and
forming a gate electrode comprising a metal semiconductor compound layer and having a predetermined gate length on the gate insulating film, the forming the gate electrode including forming a polycrystalline semiconductor film having an average grain diameter equal to a specific size or less depending on the predetermined gate length and including at least one of silicon and germanium, amorphousizing at least a part of the semiconductor film; forming a metal film on the semiconductor film; and converting whole of the semiconductor film into the metal semiconductor compound layer by reacting the semiconductor film and the metal film by heat treatment.

3. The method for manufacturing the semiconductor device according to claim 2, wherein the amorphousizing the at least a part of the semiconductor film includes implanting ions into the semiconductor film.

4. The method for manufacturing the semiconductor device according to claim 3, wherein the ions are implanted into the semiconductor film under conditions that the ions do not reach the gate insulating film.

5. The method for manufacturing the semiconductor device according to claim 2, further comprising forming a source/drain region on a surface of the semiconductor substrate, and wherein the at least the part of the semiconductor film is amorphousized before the forming the source/drain region.

6. The method for manufacturing the semiconductor device according to claim 3, further comprising forming a source/drain region on a surface of the semiconductor substrate, and wherein the at least the part of the semiconductor film is amorphousized before the forming the source/drain region.

7. The method for manufacturing the semiconductor device according to claim 1, wherein the average grain diameter of the semiconductor film is set such that amount of metal atoms of the metal film to be diffused into crystal grains of the semiconductor film becomes greater than amount of metal atoms of the metal film to be diffused into grain boundary of the semiconductor film when the whole of the semiconductor film is converted into the metal semiconductor compound layer.

8. The method for manufacturing the semiconductor device according to claim 2, wherein the average grain diameter of the semiconductor film is set such that amount of metal atoms of the metal film to be diffused into crystal grains of the semiconductor film becomes greater than amount of metal atoms of the metal film to be diffused into grain boundary of the semiconductor film when the whole of the semiconductor film is converted into the metal semiconductor compound layer.

9. The method for manufacturing the semiconductor device according to claim 1, wherein the average grain diameter is controlled to be 0.1 μm or less.

10. The method for manufacturing the semiconductor device according to claim 2, wherein the average grain diameter is controlled to be 0.1 μm or less.

11. The method for manufacturing the semiconductor device according to claim 1, wherein the average grain diameter of the semiconductor film is set such that the whole of the semiconductor film is converted into a metal semiconductor compound layer having a predetermined composition ratio.

12. The method for manufacturing the semiconductor device according to claim 2, wherein the average grain diameter of the semiconductor film is set such that the whole of the semiconductor film is converted into a metal semiconductor compound layer having a predetermined composition ratio.

13. The method for manufacturing the semiconductor device according to claim 11, wherein the metal semiconductor compound layer is a nickel silicide layer.

14. The method for manufacturing the semiconductor device according to claim 12, wherein the metal semiconductor compound layer is a nickel silicide layer.

15. The method for manufacturing the semiconductor device according to claim 1, wherein the gate electrode is a gate electrode of an n-channel and a p-channel MOS transistors in a CMOS circuit.

16. The method for manufacturing the semiconductor device according to claim 2, wherein the gate electrode is a gate electrode of an n-channel and a p-channel MOS transistors in a CMOS circuit.

17. The method for manufacturing the semiconductor device according to claim 3, wherein crystals of the semiconductor film are granular crystals.

18. The method for manufacturing the semiconductor device according to claim 1, wherein the metal film is a metal film including Er, Tm, Ni, Pd, Pt, Co, Rh, Ir, W or Mo or its compound.

19. The method for manufacturing the semiconductor device according to claim 1, wherein the gate insulating film is an insulating film higher in dielectric constant than a silicon oxide film.

20. The method for manufacturing the semiconductor device according to claim 19, wherein the gate insulating film is a first insulating film formed of oxide an element selected from a group consisting of Hf, Zr, Ti, Ta, Al, Sr, Y and La, a second insulating film formed of oxide comprising an element selected from the group, si and oxygen, or a laminated film including the first or second insulating film.
